(19) United States
(12) Patent Application Publication
(10) Pub. No.: US 2025/0372132 A1
(43) Pub. Date: Dec. 4, 2025

(54) DUAL LATCH FLIP FLOP DEVICE

(71) Applicant: UNTETHER AI CORPORATION, Toronto (CA)

(72) Inventor: Lui Ray Lam, Lexington, MA (US)

(21) Appl. No.: 18/678,885

(22) Filed: May 30, 2024

(51) Int. Cl. G11C 7/10; G11C 7/22

(52) U.S. Cl. CPC G11C 7/106; G11C 7/1057; G11C 7/222

(57) ABSTRACT

An example device includes a first latch configured to receive data and a half-clock signal and a second latch in parallel with the first latch, The second latch is configured to receive the data and an inverted half-clock signal. The device further includes an output circuit connected to data outputs of the first and second latches. The output circuit provides the data alternately from the first latch and the second latch according to the half-clock signal. The device may be used in a processing element of a single instruction, multiple data (SIMD) computing device to save power.

### BACKGROUND

In integrated circuits, a clock signal is distributed to logical elements, so that such elements may operate synchronously. A larger and more complex circuit typically requires a larger and more complex arrangement of clock routing lines.

Power is consumed due to clock routing and capacitance on the clock lines. Such power consumption is generally wasteful, and often runs counter to low-power applications.

### BRIEF DESCRIPTION OF THE DRAWINGS

FIG. 1 is a circuit diagram of an example device to provide data according to a half-clock signal.

FIG. 2 is a circuit diagram of an example circuit to generate a half-clock signal from a clock signal.

FIG. 3 is a circuit diagram of an example circuit to generate a gated half-clock signal from a clock signal.

FIG. 4 is a schematic diagram of a single instruction, multiple data (SIMD) computing device implementing the example half-clock device of FIG. 1 and the example half clock-generating circuit of FIG. 2 or 3.

FIG. 5 is a circuit diagram of an example accumulator that uses the device of FIG. 1.

### DETAILED DESCRIPTION

Disclosed herein are techniques to reduce a clock to half speed and operate a portion of a circuit at a half-clock rate. This may be applicable to complex integrated circuit that have sections of logic with different needs. It may be possible to reduce the clock speed for a particular section of an integrated circuit without affecting overall performance of the integrated circuit. This may be particularly useful in single instruction, multiple data (SIMD) computing devices, which may be termed at-memory or massively parallel computing devices.

Disclosed herein are device/circuits that use latches to implement flip-flop functionality, which may be useful in general and, in particular, in reduced-or half-clock rate applications. The techniques described herein offer significant energy reduction in registers where data activity is relatively low. Example applications include accumulators, but other applications will be apparent to those of ordinary skill in the art given the benefit of this disclosure. The devices/circuits discussed herein may be useful anywhere data activity is relatively low and clock power consumes a significant or dominant amount of energy.

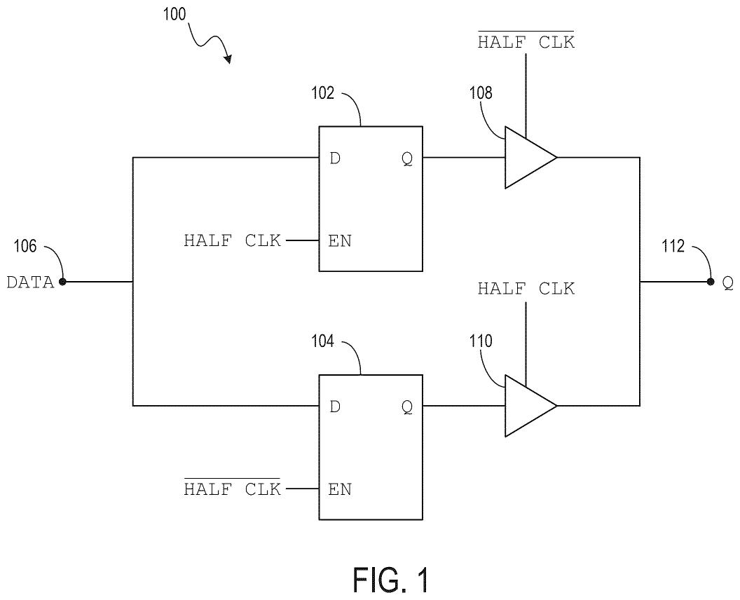

FIG. 1 shows an example device 100. The device 100 may be implemented as logic circuity provided at an integrated circuit, i.e., a chip. The device 100 may be used to operate a section of an integrated circuit at a reduce clock rate, such as half a normal clock speed. In this and other applications, the device 100 may replace a conventional flip flop.

The device 100 includes a pair of D latches 102, 104 arranged in parallel. A first D latch 102 is connected to lines to receive data (“DATA”) at its data input D and a half-clock signal HALF CLK at its enable input EN. A second D latch 104 is connected to lines to receive the same data at its data input D and an inverted half-clock signal H̅A̅L̅F̅ C̅L̅K̅ at its enable input EN. In this example, the latches are D latches. In other examples, other kinds of latches, such as SR latches, may be used.

In the examples discussed herein, the half-clock signal HALF CLK has half the frequency of a clock signal CLK provided to other components of a circuit that contains the device 100. The half-clock signal HALF CLK may share other properties, such as voltage, amplitude, pulse width, etc., of the clock signal CLK.

The device 100 further includes a main input 106 at which the data is provided to the pair of D latches 102, 104.

The device 100 further includes an output circuit connected to the data outputs Q of the first and second D latches 102, 104. The output circuit provides the data output Q alternately from the first D latch and the second D latch according to the half-clock signal HALF CLK. In this example, a first tri-state buffer 108 has its input connected to the data output Q of the first D latch 102 and its enable input connected to the inverted half-clock signal H̅A̅L̅F̅ C̅L̅K̅. Similarly, a second tri-state buffer 110 has its input connected to the data output Q of the second D latch 104 and its enable input connected to the half-clock signal HALF CLK. In other examples, one or both of the tri-state buffers 108, 110 is replaced with a transmission gate.

The device 100 further includes a main output 112, which in this example is connected to the outputs of the tri-state buffers 108, 110, to take the output data Q from the pair of D latches 102, 104.

In operation, data is provided to the main input 106 and thus the data inputs D of the pair of D latches 102, 104. The half-clock signal HALF CLK is provided to enable the pair of D latches 102, 104 in an alternate manner by way of the D latches 102, 104 respectively receiving the half-clock signal HALF CLK and its inverted counterpart H̅A̅L̅F̅ C̅L̅K̅. As such, the main output 112 provides the data from the pair of D latches 102, 104 in an alternate manner via the alternately enabled tri-state buffers 108, 110. While one of the latches 102, 104 samples data, the other of the latches 102, 104 holds data.

In this example, the first (upper in the diagram) and second (lower) legs of the device 100 have the same components, i.e., a D latch and a tri-state buffer. Accordingly, it is expected to have identical or near identical output impedance regardless of which of the first or second leg currently drives the output.

The device 100 may be considered a dual-edge D flip flop and may be used to replace a conventional D flip flop.

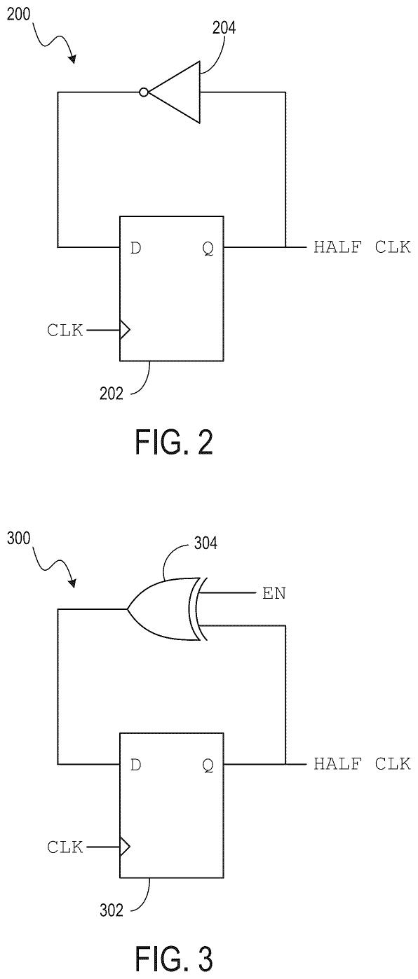

FIG. 2 shows an example circuit 200 to output a half-clock signal HALF CLK that may be provided to the device 100.

The circuit 200 includes a flip flop 202, such as a D flip flop. A full clock signal CLK is provided to the enable input of the flip flop 202. The circuit 200 further includes an inverter 204 connected to the flip flop 202 such that inverted data output Q of the flip flop 202 is fed back as data input D to the flip flop 202. In operation, the circuit 200 generates the half-clock signal HALF CLK from the clock signal CLK provided as an enable signal to the flip flop 202.

Gating of the half-clock signal HALF CLK may be performed with the circuit 200 by gating the input clock signal CLK.

FIG. 3 shows an example circuit 300 to output a gated half-clock signal HALF CLK that may be provided to the device 100.

The circuit 300 includes a flip flop 302, such as a D flip flop. A full clock signal CLK is provided to the enable input of the flip flop 302. The circuit 300 further includes a XOR gate 304 connected to the flip flop 302. The XOR gate 304 takes as input the data output Q of the flip flop 402 and an enable signal (control signal) EN. Output of the XOR gate 304 is fed back as data input D to the flip flop 302. In operation, the circuit 300 generates a gated half-clock signal HALF CLK from the clock signal CLK provided as an enable signal to the flip flop 302 and an enable signal (control signal) EN provided to the XOR gate 304.

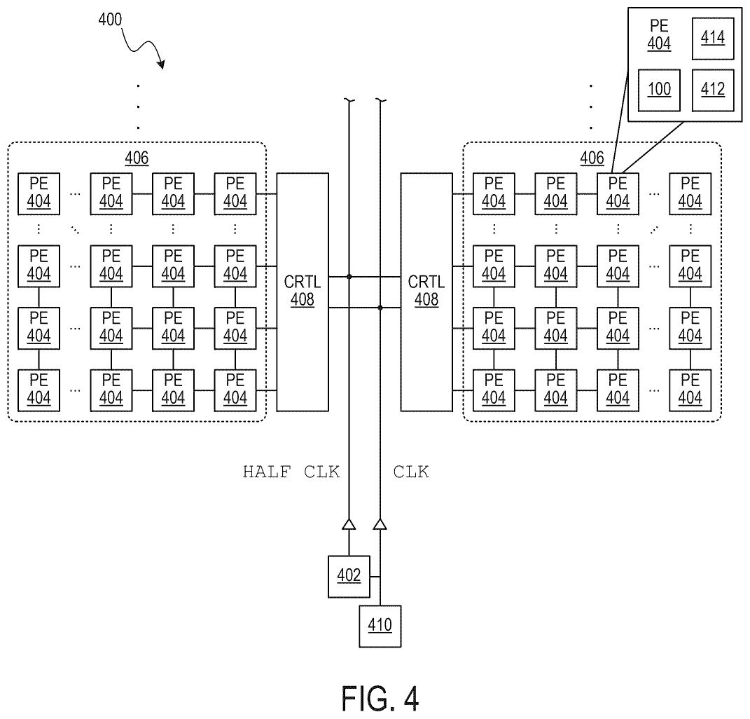

FIGS. 4 shows a SIMD computing device 400 that implements the example half-clock device 100 with an example half clock-generating circuit 402, such as the circuit 200 or 300.

The SIMD computing device 400 includes an array of processing elements 404 configured to operate in SIMD fashion. The device 400 may include hundreds, thousands, or hundreds of thousands of processing elements 404. At least one of the processing elements 404 includes a half-clock device 100.

The SIMD computing device includes multiple banks 406 of processing elements 404. The bank 406 is a computing device, which may be termed a SIMD or at-memory computing device. U.S. Pat. No. 11,881,872, which is incorporated herein by reference, may be referenced for additional details concerning processing elements 404 and banks 406 thereof.

A bank 406 includes an array of processing elements or PEs 404. Processing elements 404 may be logically and, optionally, physically arranged in a two-dimensional array. Such an array may be considered to have rows and columns.

Each processing element 404 includes operational circuitry 412 to perform operations, such as multiplying accumulations. For example, each processing element 404 may include a multiplying accumulator and supporting circuitry. The processing element 404 may additionally or alternatively include an arithmetic logic unit (ALU).

Each processing element 404 may include a device 100 or multiple devices 100, which may be termed a half-clock circuit in this example, to perform operations at a reduced clock rate. A device 100 may form part of the operational circuitry 412. For example, the operational circuity 412 may include an accumulator and instances of the device 100 may be used in the accumulator and where flip flops might otherwise be used.

Each processing element 404 includes or is connected to working memory 414 dedicated to that processing element 404. A processing element 404 may be connected with one or more neighboring processing elements 404 to share data and/or instructions. Processing element interconnections may be provided in the row direction, the column direction, or both.

The bank 406 further includes a controller 408 connected to the processing elements 404. The controller 408 is a processor (e.g., microcontroller, etc.) that may be configured with instructions to control the connected processing elements 404.

The controller 408 controls the connected processing elements 404 to perform the same operation on different data contained in each processing element 404. The controller 408 may further control the loading/retrieving of data to/from the processing elements 404, control the communication among processing elements 404, and/or control other functions for the processing elements 404. Any suitable number of controllers 408 may be provided to control the processing elements 404. Controllers 408 may be connected to each other for mutual communications. Controllers 408 may be arranged in a hierarchy, in which, for example, a main controller controls sub-controllers, which in turn control subsets of processing elements 404.

A clock circuit 410 generates and provides a clock signal CLK.

The half clock-generating circuit 402 is connected to the clock circuit 410 and receives the clock signal CLK. The half clock-generating circuit 402 generates a half-clock signal HALF-CLK.

The full clock signal CLK and half-clock signal HALF CLK may be selectively provided to the processing elements 404. For examples, clock lines may be routed to each controller 408 and from the controller 408 to the respective processing elements 404. Switches may be provided to selectively communicate one or more of the clocks to the banks 406. A bank 406 may be provided with only the clock it needs, so as to save power.

Each processing element 404 receives one or both of the clock signal CLK and the half-clock signal HALF CLK, the latter of which is routed to the half-clock circuit 100 of the processing element 404. The processing element 404 performs operations, in unison with other respective processing elements 404 as commanded by the respective controller 408, using the operational circuitry 412 and memory 414. The processing element 404 may perform such operations using the half-clock signal HALF CLK and half-clock circuit 100 if so commanded by the controller 408.

Operating the different subsets or banks 406 of processing elements 404 at different clock rates may be useful to save power, avoid blocking, and/or to maintain synchronized operations when different subsets or banks 406 of processing elements 404 perform different computations that take different amounts of times.

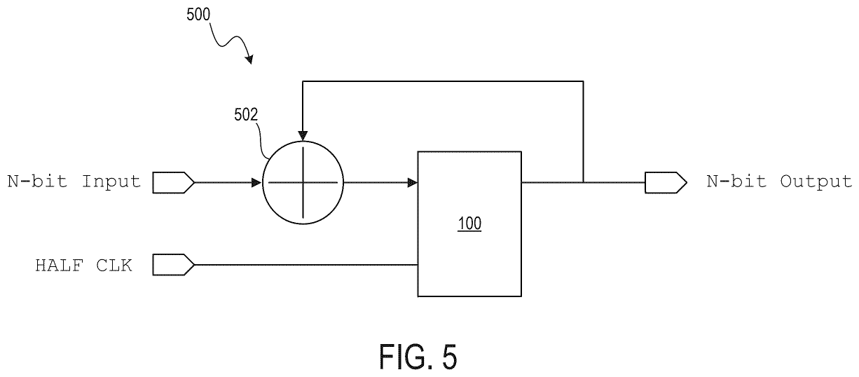

FIG. 5 shows an example accumulator 500 that uses the device 100, as described above. The accumulator 500 may be provided to a processing element 404 and may be part of the operational circuitry 412 of such a processing element 404 (see FIG. 4). The accumulator 500 includes an adder 502 that adds an N-bit input to an N-bit output of the device 100. Output of the adder 502 is connected to the data input of the device 100.

In view of the above, it should be understood that that a clock may be reduced to a half clock using a parallel pair of latches instead of more complex conventional circuitry. This may be particularly useful for SIMD computing devices, which may have complex clock trees that serve large arrays of processing elements that perform operations with different timing. Power consumed by the clock may be reduced by about 50% for sections of a circuit that can be operated effectively at the half clock rate.

1. A device comprising:
a first latch configured to receive data and a half-clock signal;
a second latch in parallel with the first latch, the second latch configured to receive the data and an inverted half-clock signal; and
an output circuit connected to data outputs of the first and second latches, the output circuit to provide the data alternately from the first latch and the second latch according to the half-clock signal.

2. The device of claim 1, further comprising a flip flop configured to generate the half-clock signal from a clock signal provided to an enable input, wherein inverted output is provided as input, and wherein output is the half-clock signal.

3. The device of claim 1, wherein the output circuit comprises:
a first tri-state buffer having an input connected to a data output of the first latch and being enabled by the inverted half-clock signal; and
a second tri-state buffer having an input connected to a data output of the second latch and being enabled by the half-clock signal;
wherein outputs of the tri-state buffers provide the data alternately from the first latch and the second latch.

4. A device comprising:
a pair of latches arranged in parallel;
a main input providing data to the pair of latches; and
a main output taking the data from the pair of latches;
wherein a half-clock signal is provided to enable the pair of latches in an alternate manner, such that the main output provides the data from the pair of latches in an alternate manner.

5. The device of claim 4, further comprising a flip flop to generate the half-clock signal from a clock signal provided as an enable signal, the flip flop having inverted output fed back as input, wherein the flip flop provides the half-clock signal as output.

6. The device of claim 4, further comprising a pair of tri-state buffers, each connected to a data output of a respective one of the pair of latches and enabled by the half-clock signal in an alternate manner, wherein outputs of the pair of tri-state buffers are connected to the main output.

7. The device of claim 1, wherein the first latch is a D latch and the second latch is a D latch.

8. A computing device comprising:
an array of processing elements configured for single instruction, multiple data (SIMD) operation; and
a controller connected to the array of processing elements to control the array of processing elements to perform the SIMD operation;
wherein at least one of the processing elements includes a circuit that operates according to a half-clock signal that has half the frequency of a clock signal provided to the computing device, the circuit including a pair of latches arranged in parallel, wherein the half-clock signal is provided to enable the pair of latches in an alternate manner, such that the circuit provides data from the pair of latches in an alternate manner.

9. The computing device of claim 8, wherein the circuit is included in an accumulator of the at least one of the processing elements.

10. The computing device of claim 8, wherein the pair of latches is a pair of D latches.
